(19) United States
(12) Patent Application Publication
(10) Pub. No.: US 2002/0127847 A1
(43) Pub. Date: Sep. 12, 2002

(54) Electrochemical co-deposition of metals for electronic device manufacture

(75) Inventors: Eric R. Alling, Upton, MA (US); Martin W. Bayes, Hopkinton, MA (US)

Correspondence Address: S. Matthew Cairns, c/o EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA (US)

(21) Appl. No.: 10/008,665

(22) Filed: Nov. 3, 2001

Related U.S. Application Data
(60) Provisional application No. 60/245,937, filed on Nov. 3, 2000.

(51) Int. Cl. H01L 21/4763

(52) U.S. Cl. 438/630

(57) ABSTRACT

New compositions and methods for electrolytic deposition of metal layers, including metal traces, (e.g. circuit patterns) that are electrically segregated from adjacent traces in an electronic device, such as a semiconductor wafer or a printed circuit board. The invention includes providing the segregated traces by compositionally modulated plating methods, i.e. for example where a single plating bath (electrolyte) is employed to deposit two different metals at differing current densities or reduction potentials.

### BACKGROUND OF THE INVENTION

1. Field of the Invention

The present invention includes new compositions and methods for electrolytic deposition of metal layers, including metal traces (e.g. circuit patterns) that are electrically segregated from adjacent traces in an electronic device. The invention includes providing the segregated traces by compositionally modulated plating methods, i.e. for example where a single plating bath (electrolyte) is employed to deposit two different metals at differing current densities or reduction potentials.

2. Background

Demands for increased density and performance of semiconductor chips and other electronic devices place constant pressures on manufacturers to improve interconnection technology.

A typical semiconductor device may comprise a semiconductor substrate such as doped monocrystalline silicon, and multiple dielectric layers and conductive traces. The integrated circuit is formed by a series of conductive patterns that include conductive traces (lines) separated by interwiring spacing. Conductive patterns formed in different layers of the semiconductor are electrically connected by via holes or other aperatures between the layers that are filled with conductive metal.

Typically, aluminum (Al) has been employed for chip interconnections. However, industry continually demands enhanced performance, including ultra-large scale integration and faster circuits. Consequently, chip interconnects are required at critical dimensions of 200 nm or less.

More recently, copper plating also has been employed in semiconductor chip manufacture to provide chip interconnections. Traditionally, semiconductors have been interconnected through aluminum conductors. However, industry continually demands enhanced performance, including ultra large-scale integration and faster circuits. Consequently, chip interconnects are required at dimensions of 200 nm and less. At such geometries, the resistivity of aluminum (theoretically 2.65×10⁸ ohm/meter at room temperature) is considered too high to allow the electronic signal to pass at required speeds. Copper, with a theoretical resistivity of 1.678×10⁸ ohm/meter, is considered a more suitable material to meet the next generation of semiconductor microchips.

Typical processes for defining semiconductor chip interconnects, particularly aluminum interconnects, have involved reactive ion etching of metal layers, e.g. a process that includes metal deposition, photolithographic patterning, line definition through reactive ion etching and dielectric deposition. However, in copper-based systems, reactive ion etching is not practical as a result of the paucity of copper compounds with vapor pressures sufficient to enable removal of the copper as may be desired.

Copper also can diffuse through silicon dioxide, a common dielectric interlayer material employed in the manufacture of semiconductor devices, where such diffusion can adversely affect device performance. See U.S. Pat. No. 6,022,808. In particular, such copper diffusion can result in undesired leading to shortage of the circuits, or current leakage between adjacent circuit traces.

It thus would be desirable to have new methods for manufacture of electronic devices, including semiconductor chips and semiconductor packaging. It thus would be particularly desirable to have new methods to produce copper circuit patterns in electronic devices wherein the copper circuits do not exhibit undesired electromigration or current leakage during use.

### SUMMARY OF THE INVENTION

The invention includes new compositions and methods for the production of metal films or layers, including metal traces (e.g. circuit patterns) that are electrically segregated from adjacent traces in electronic device manufacture. Copper is a preferred deposition metal to provide circuit interconnections, although other metals also can be suitably deposited in accordance with the invention. Preferably, compositionally modulated plating methods are utilized, wherein a single plating bath (electrolyte) is employed to deposit two or more different metals at differing current densities or reduction potentials.

In preferred aspects of the invention, first and second circuit patterns are electrolytically deposited with an interposed barrier-type or dopant layer. The barrier layer can prevent undesired electromigration from the circuit pattern metal, and thus avoid defects such as current leakage. In the case where one or both of the first and second circuit patterns are comprised of copper, the barrier layer of a lesser conductive material or dopant such as zinc or phosphorus interposed with the circuit metal such as copper, can prevent undesired migration of copper and copper ions (particularly diffusion into dielectric layers) and hence limit or reduce device defects such as current leakage.

The segregated circuit traces are formed via compositionally modulated plating methods, i.e. for example where a single plating bath (electrolyte) is employed to deposit two different metals at differing current densities. For example, a single plating bath can be employed that contains both i) copper metal source and ii) a barrier layer source such as an alloy of copper and/or one or more of zinc, tantalum, phosphorus, beryllium, magnesium, nickel, titanium, tin, palladium, silver, and cadmium which can function as dopants. At a first reduction potential, copper can be deposited, and a second reduction potential the barrier (dopant) layer material such as a copper alloy can be deposited. Other materials can be employed as barrier layers, including metals or alloys that do not include copper. However, a copper alloy is a generally preferred dopant layer material employed with copper circuit layers.

Thus, in a single plating vessel or sequence, multiple circuit patterns with interposed barrier layers can be formed on an electronic device substrate, providing a significantly enhanced and streamlined manufacturing process. Additionally, circuit traces of improved quality can be produced, particularly without any detrimental diffusion of the conductive material (e.g. copper) that could result in device defects such as undesired current leakage.

When plating copper as a conductive material, preferably a substantially homogenous copper layer is deposited, e.g. the layer consists of at least about 90 or 95 weight percent, 96 weight percent, 97 weight percent, 98 weight percent, 99 weight percent, or 99.5 weight percent copper. Such copper layers can be effective conductors, e.g. serve as an electrical circuit, as discussed above.

The second metal plated, e.g. less conductive metal such as a doped copper alloy, is preferably substantially less conductive than the first metal plated, e.g. a substantially homogenous copper layer. That is, an electrical signal can be transmitted through the first metal layer without migration or electrical defects or the like into the second metal layer.

In another aspect, the invention provides methods and articles for electrolytic deposition of compositions that can be employed as a solderable finish or a metal resist, particularly tin-containing compositions employed in the manufacture of printed circuit boards and other electronic packaging devices. Compositionally modulated plating methods are utilized to deposit compositions suitable for use as solderable finishes or metal resists. Preferred compositions deposited do not contain lead, and may be mixtures of tin and one or more other metals, such as silver, cobalt, and the like.

The invention further comprises articles of manufacture comprising substrates such as a microelectronic device substrate, particularly a semiconductor chip substrate, having plated thereon compositions of the invention, including first and second circuit traces separated by a barrier layer, obtainable by methods of the invention. The invention still further comprises articles of manufacture comprising substrates such as a microelectronic device such as semiconductor ships or semiconductor packaging having plated thereon solderable finish compositions of the invention.

Other aspects of the invention are disclosed infra.

### DETAILED DESCRIPTION OF THE INVENTION

As discussed above, the invention provides new methods for deposition of metal layers, including compositionally modulated plating methods that can provide distinct metal layer plates.

Preferred plating solutions in accordance with the invention are baths, including both aqueous and non-aqueous solutions, that contain sources of the plating metals to be deposited. The solutions can be acidic or alkaline or even substantially neutral, although acidic solutions are generally preferred. Suitable acid sources include e.g. sulfuric acid, hydrochloric acid and the like. Plating compositions of the invention also suitably will contain one or more additives to enhance quality of the plated metal, such as brighteners, levelers and the like.

A variety of metals can be plated in accordance with the invention. The plating bath should be able to deposit two materials of distinct resistivities. Preferably, the two materials are of sufficiently distinct resistivity so that the first deposited material can effectively transmit an electric signal and the second material will act as a resistive layer, i.e. the second layer is substantially less conductive than the first layer.

As discussed above, a preferred first material for deposition that can function as a circuit layer is copper, although other conductive materials also may be employed e.g. gold, nickel, silver, and the like. Compositions suitable for depositing solderable finishes typically include tin and one or more conductive metals, such as, but not limited to, copper, silver, cobalt, indium, nickel, bismuth, zinc and antimony. Particularly useful solderable finishes are tin-silver, tin-bismuth, tin-nickel, and tin-indium.

Preferred electroplating compositions of the invention for depositing copper contain a copper source typically a copper salt, a source for plating a second metal material, and an electrolyte preferably an acidic aqueous solution such as a sulfuric acid solution with a chloride or other halide ion source. The electroplating baths may contain other components such as one or more brightener agents, one or more suppressor agents, one or more leveler agents, and the like.

A variety of copper salts may be employed in the electroplating compositions for deposition of copper, including salts such as copper sulfates, copper acetates, copper tetrafluoroborate, and cupric nitrates. Copper sulfate pentahydrate is a particularly preferred copper salt. A copper salt may be suitably present in a relatively wide concentration range in the electroplating compositions of the invention. Preferably, a copper salt will be employed at a concentration of from about 10 to about 300 grams per liter of plating solution, more preferably at a concentration of from about 25 to about 200 grams per liter of plating solution, still more preferably at a concentration of from about 40 to about 175 grams per liter of plating solution.

A wide variety of tin compounds may be employed in the present compositions for the deposition of tin. Suitable tin compounds include, but are not limited to salts, such as tin halides, tin sulfates, tin alkane sulfonate such as tin methane sulfonate, tin aryl sulfonate such as tin phenyl sulfonate and tin toluene sulfonate, tin alkanol sulfonate, and the like. It is preferred that the tin compound is tin sulfate, tin chloride, tin alkane sulfonate or tin aryl sulfonate, and more preferably tin sulfate or tin methane sulfonate. The amount of tin compound useful in the electrolyte compositions of the present invention is any amount that provides a tin content typically in the range of 5 to 150 g/L, and preferably 10 to 70 g/L. Mixtures of tin compounds may also be used advantageously in the present invention, provided that the total amount of tin is in the range of from 5 to 150 g/L. A variety of materials may be used as the second metal source in plating compositions of the invention. Such materials are typically added to the plating compositions in any soluble form. The material should be capable of depositing either alone or as a copper alloy or as a tin alloy at a current density distinct from the current density where a substantially homogenous copper plate or tin plate (first metal) can be deposited. Preferably, the second metal will plate at a current density of at least about 1, 2, 3, 4, or 5 amps per square foot (ASF) different than the current density at which a substantially homogenous copper or tin layer will be deposited from the same plating bath, more preferably the second metal will plate at a current density of at least about 6, 7, 8, 9, 10, 12, 15, 18 or 20 ASF different than the current density at which a substantially homogenous copper or tin layer will be deposited from the same plating bath.

Similarly, the reduction potential difference between the first metal plated and a second metal plated in accordance with the invention is preferably at least about 0.1 V, more preferably at least about 0.2, 0.3, 0.4, 0.5, 0.6, 0.7, 0.8, 0.9, 1.0, 1.5, 2, 3, 4 or 5 V reduction potential difference between the first metal plated (e.g. copper) and the second metal plated (e.g. copper alloy such as copper with phosphorus, zinc, etc.)

Additionally, the material that is used as the second metal source should provide a metal layer that has greater resistivity (less conductive) than the first metal plate. The second metal source can have reduced ion mobility relative to the first layer conductive masterial. For instance, suitably the second metal source provides a metal plate that has a resistivity at least about 10 percent greater (e.g. in units of ohm-cm) than the resistivity of the first electrically conductive layer (e.g. copper layer), more preferably a resistivity of at least about 20, 30, 40, 50, 60, 70, 80, 90, 100, 125, 150, 200, 300, 400 or 500 percent greater than (e.g. in units of ohm-cm) than the resistivity of the first electrically conductive layer (e.g. copper layer)

More particularly, the material used as the second metal source suitably may comprise zinc, bismuth, indium, copper (in the use where the first metal is tin), cobalt, antimony, tantalum, nickel, beryllium, magnesium, titanium, tin, palladium, silver, platinum, gold, and cadmium. Those materials may be deposited alone or more typically as an alloy of the first metal (less resistive) material. At least some of those materials would be more preferably deposited from non-aqueous compositions, e.g. tantalum, magnesium, beryllium, titanium, etc.

Plating baths of the invention preferably employ an acidic electrolyte, which typically will be an acidic aqueous solution and that preferably contains a halide ion source, particularly a chloride ion source. Examples of suitable acids for the electrolyte include sulfuric acid, acetic acid, fluoroboric acid, and alkane or aryl sulfonic acids, such as methane sulfonic acid, ethane sulfonic acid, propane sulfonic acid, phenyl sulfonic acid, and toluene sulfonic acid. Sulfuric acid is generally preferred for copper and alkane or aryl sulfonic acids for tin. Chloride is a generally preferred halide ion. A wide range of halide ion concentrations (if a halide ion is employed) may be suitably utilized, e.g. from about 0 (where no halide ion employed) to 100 parts per million (ppm) of halide ion in the plating solution, more preferably from about 25 to about 75 ppm of halide ion source in the plating solution.

The invention also includes electroplating baths that are substantially or completely free of an added acid and may be neutral or essentially neutral (e.g. pH of from about 4 to 9). Such plating compositions are suitably prepared in the same manner with the same components as other compositions disclosed herein but without an added acid.

As discussed above, plating baths of the invention may suitably comprise one or more additives, typically organic materials, to enhance the characteristics of the deposited metal layers.

Electroplating baths for deposition of copper in accordance with the invention also preferably contain a brightener agent. A wide variety of brightener agents may be employed, including known brightener agents, may be suitably employed. Typical brighteners contain one or more sulfur atoms, and typically without any nitrogen atoms and a molecular weight of about 1000 or less. Brightener compounds that have sulfide and/or sulfonic acid groups are generally preferred, particularly compounds that comprise a group of the formula R′—S—R—SO₃X, where R is an optionally substituted alkyl (which include cycloalkyl), optionally substituted heteroalkyl, optionally substituted aryl group, or optionally substituted heteroalicyclic; X is a counter ion such as sodium or potassium; and R′ is hydrogen or a chemical bond (i.e. —S—R—SO₃X or substituent of a larger compound). Typically alkyl groups will have from one to about 16 carbons, more typically one to about 8 or 12 carbons. Heteroalkyl groups will have one or more hetero (N, O or S) atoms in the chain, and preferably have from 1 to about 16 carbons, more typically 1 to about 8 or 12 carbons. Carbocyclic aryl groups are typical aryl groups, such as phenyl and naphthyl. Heteroaromatic groups also will be suitable aryl groups, and typically contain 1 to about 3 N, O or S atoms and 1-3 separate or fused rings and include e.g. coumarinyl, quinolinyl, pyridyl, pyrazinyl, pyrimidyl, furyl, pyrrolyl, thienyl, thiazolyl, oxazolyl, oxidizolyl, triazole, imidazolyl, indolyl, benzofuranyl, benzothiazol, and the like. Heteroalicyclic groups typically will have 1 to 3 N, O or S atoms and from 1 to 3 separate or fused rings and include e.g. tetrahydrofuranyl, thienyl, tetrahydropyranyl, piperdinyl, morpholino, pyrrolindinyl, and the like. Substituents of substituted alkyl, heteroalkyl, aryl or heteroalicyclic groups include e.g. C₁₋₈ alkoxy; C₁₋₈ alkyl, halogen, particularly F, Cl and Br; cyano; nitro, and the like.

More specifically, useful brighteners include those of the following formulae:

XO₃S—R—SH

XO₃S—R—S—S—R—SO₃ X and

XO₃S—Ar—S—S—Ar—SO₃X

where in the above formulae R is an optionally substituted alkyl group, and preferably is an alkyl group having from 1 to 6 carbon atoms, more preferably is an alkyl group having from 1 to 4 carbon atoms; Ar is an optionally substituted aryl group such as optionally substituted phenyl or naphthyl; and X is a suitable counter ion such as sodium or potassium.

Some specific suitable brighteners include e.g. N,N-dimethyl-dithiocarbamic acid-(3-sulfopropyl)ester; 3-mercapto-propylsulfonic acid-(3-sulfopropyl)ester; 3-mercapto-propylsulfonic acid (sodium salt); carbonic acid-dithio-o-ethylester-s-ester with 3-mercapto-l-propane sulfonic acid (potassium salt); bissulfopropyl disulfide; 3-(benzthiazolyl-s-thio)propyl sulfonic acid (sodium salt); pyridinium propyl sulfobetaine; 3-mercaptopropane-l-sulfonate sodium salt; sulfoalkyl sulfide compounds disclosed in U.S. Pat. No. 3,778,357; the peroxide oxidation product of a dialkyl amino-thiox-methyl-thioalkanesulfonic acid; and combinations of the above. Additional suitable brighteners are also described in U.S. Pat. Nos. 3,770,598, 4,374,709, 4,376,685, 4,555,315, and 4,673,469, all incorporated herein by reference. Particularly preferred brighteners for use in the plating compositions of the invention are N,N-dimethyl-dithiocarbamic acid-(3-sulfopropyl)ester and bis-sodium-sulfonopropyl-disulfide.

In particular, copper electroplating compositions are provided that have a brightener agent concentration of at least about 1.5 mg per liter of plating solution (1.5 mg/L), compared to typical brightener concentrations ranging from about 0.05 to 1.0 mg/L in prior composition. More preferably, in electroplating baths of the invention, the brightener concentration is at least about 1.75 mg/L, and still more preferably, at least about 2, 2.5, 3, 3.5 or 4 mg/L. Even higher brightener concentrations will be suitable or even preferred, e.g. at least about 10, 15, 20, 30, 40, 50 mg of brightener per liter of plating solution. A brightener concentration of from about 20 to about 200 mg per liter of plating solution will be suitable for many applications.

Preferably a relatively high brightener concentration is employed, e.g. a concentration of at least about 1.5 mg of brightener per liter of plating solution.

In addition to the copper salts, electrolyte and brightener, plating baths of the invention optionally may contain a variety of other components, including organic additives such as suppressors agents, leveling agents and the like.

Preferred suppressor agents for use in the compositions of the invention are polymeric materials, preferably s having hetero atom substitution, particularly oxygen linkages. Generally preferred suppressor agents ate generally high molecular weight polyethers, such as those of the following formula:

R—O—(CXYCX′Y′O)ₙH

where R is an aryl or alkyl group containing from about 2 to 20 carbon atoms; each X, Y, X′ and Y′ is independently hydrogen; alkyl preferably methyl, ethyl or propyl; aryl such as phenyl; aralkyl such as benzyl, and preferably one or more of X, Y, X′ and Y′ is hydrogen; and n is an integer between 5 and 100,000. Preferably, R is ethyl and n is greater than 12,000.

More specifically, suppressor agents useful in the present invention include e.g. a amines such as ethoxylated amines, polyoxyalkylene amines and alkanol amines; amides; polyglycol-type wetting agents, such as polyethylene glycols, polyalkylene glycols and polyoxyalkyene glycols; high molecular weight polyethers; polyethylene oxides (mol. wt. 300,000 to 4 million); block copolymers of polyoxyalkyenes; alkylpolyether sulfonates; complexing surfactants such as alkoxylated diamines; and complexing agents for cupric or cuprous ions which include entprol, citric acid, edetic acid, tartaric acid, potassium sodium tartrate, cuproine and pyridine.

Particularly suitable suppressor agents for plating compositions of the invention are commercially available polyethylene glycol copolymers, including polyethylene glycol copolymers. Such polymers are available from e.g. BASF (sold by BASF under Tetronic and Pluronic tradenames), and copolymers from Chemax. A butylalcohol-ethylene oxide-propylene oxide copolymer having an M_{W}, of about 1800 from Chemax is particularly preferred.

Such suppressor agents are typically added to copper electroplating solutions in concentrations ranging from about 1 to 10,000 ppm based on the weight of the bath, more preferably about 5 to 10,000 ppm.

When tin is used in the present compositions, suitable non-ionic surfactants or wetting agents include, but are not limited to: relatively low molecular weight ethylene oxide (“EO”) derivatives of aliphatic alcohols containing an alkyl group of up to 7 carbons or ethylene oxide derivatives of aromatic alcohols having up to two aromatic rings, which may be fused and which may be substituted with an alkyl group having up to 6 carbons. The aliphatic alcohols may be saturated or unsaturated. The aromatic alcohols typically have up to 20 carbon atoms prior to derivatization with ethylene oxide. Such aliphatic and aromatic alcohols may be further substituted, such as with sulfate or sulfonate groups. Suitable wetting agents include, but are not limited to: ethoxylated polystyrenated phenol containing 12 moles of EO, ethoxylated butanol containing 5 moles of EO, ethoxylated butanol containing 16 moles of EO, ethoxylated butanol containing 8 moles of EO, ethoxylated octanol containing 12 moles of EO, ethoxylated octylphenol containing 12 moles of EO, ethoxylated/propoxylated butanol, ethylene oxide/propylene oxide block copolymers, ethoxylated beta-naphthol containing 13 moles of EO, ethoxylated beta-naphthol containing 10 moles of EO, ethoxylated bisphenol A containing 10 moles of EO, ethoxylated bisphenol A containing 13 moles of EO, sulfated ethoxylated bisphenol A containing 30 moles of EO, and ethoxylated bisphenol A containing 8 moles of EO. Typically, such wetting agents are added in an amount of 0.1 to 20 g/L, and preferably 0.5 to 10 g/L.

Use of one or more leveling agents in plating baths, particularly copper plating baths, of the invention also is generally preferred. Examples of suitable leveling agents are described and set forth in U.S. Pat. Nos. 3,770,598, 4,374,709, 4,376,685, 4,555,315 and 4,673,459. In general, useful leveling agents include those that contain a substituted amino group such as compounds having R—N—R′, where each R and R′ is independently a substituted or unsubstituted alkyl group or a substituted or unsubstituted aryl group. Typically the alkyl groups have from 1 to 6 carbon atoms, more typically from 1 to 4 carbon atoms. Suitable aryl groups include substituted or unsubstituted phenyl or naphthyl. The substituents of the substituted alkyl and aryl groups may be, for example, alkyl, halo and alkoxy.

More specifically, suitable leveling agents include e.g. 1-(2-hydroxyethyl)-2-imidazolidinethione; 4-mercaptopyridine; 2-mercaptothiazoline; ethylene thiourea; thiourea; alkylated polyalkyleneimine; phenazonium compounds disclosed in U.S. Pat. No. 3,956,084; N-heteroaromatic rings containing polymers; quaternized, acrylic, polymeric amines; polyvinyl carbamates; pyrrolidone; and imidazole. A particularly preferred leveler is 1-(2-hydroxyethyl)-2-imidazolidinethione. Typical concentrations of leveling agents range from about 0.05 to 0.5 mg per liter of plating solution.

Reducing agents may be added to the electrolyte composition of the present invention to assist in keeping the tin in a soluble, divalent state. Suitable reducing agents include, but are not limited to, hydroquinone and hydroxylated aromatic compounds, such as resorcinol, catechol, and the like. Suitable reducing agents are those disclosed in U.S. Pat. No. 4,871,429. The amount of such reducing agent is well known to those skilled in the art, but is typically in the range of from about 0.1 g/L to about 5 g/L.

A substrate suitably may be plated in accordance with the invention by a pulse plating protocol, wherein as discussed above a first metal is plated at a first reduction density, and a second distinct metal is plated at a second reduction potential distinct from the first reduction potential. For instance, if the first and second metal materials plate effectively at a reduction potential differential of about 5 V, a substrate (e.g. a semiconductor chip substrate) can be immersed in a plating composition as discussed above, with the substrate serving as an electrode. The plating bath may be suitably at or above room temperature, e.g. up to and somewhat above 65° C. The plating composition is preferably agitated during use such as by air sparger, work piece agitation, impingement or other suitable method. Plating is preferably conducted at a current ranging from 1 to 40 ASF depending upon substrate characteristics. Even higher current densities may be employed if desired, e.g. at from 50 to 100, 200, 300, 400 or 500 or more ASF. Plating time may range from about 5 minutes to 1 hour or more, depending on e.g. the number of metal layers deposited and the difficulty of the work piece.

During the plating sequence, the potential is modulated as desired. Length of each plating cycle will generally dictate the thickness of the particular layer deposited. For instance, the plating composition can be ramped to a first current density for a defined period, e.g. 0.25 seconds, 0.5, 0.75, 1, 2, 3, 4, 5, 10, 20, 30, 40, 50 or 60 seconds or more, followed by a “pulse” of a second current density that is maintained for a defined period, e.g. 0.25 seconds, 0.5, 0.75, 1, 2, 3, 4, 5, 10, 20, 30, 40, 50 or 60 seconds or more, and then the first current is again “pulsed” for a defined period, and then the second current is again pulsed for a defined period and so on. The number of pulses will provide the number of metal layers deposited.

Metal layer thickness also may suitably vary. For instance, suitable metal layers may be at least about 20 nm thick, more typically at least about 25, 30, 40, 50, 60 70, 80, 90 or 100 nm thickness per layer. A variety of other layer thickness also may be employed such as up to 0.5 microns. Different layer thicknesses may be employed for distinct layers in a series of plated metals.

Compositionally modulated plating in accordance with the invention can be carried out either manually, semi-manually or via an automated system. Automated systems are generally preferred to provide metal depositions of enhanced quality as well as reproducibility with respect to thickness and boundary of each layer, and the like. A certain automated plating system has been described in D. Rani et al., Nanotechnology, 7: 143-143 (1996).

A wide variety of substrates may be plated in accordance with the invention. However, preferably electronic device substrates and opto-electronic device substrates are plated in accordance with the invention to provide multiple circuit layers. Exemplary electronic devices include integrated circuit substrates such as semiconductor substrates, including multichip modules, and other electronic packaging substrates such as lead frames. Printed circuit boards also can be plated in accordance with the invention, particularly with respect to deposition of a solder resist, or electronic components with a solderable finish. Other suitable substrates include, but are not limited to, chip capacitors and chip resistors.

For instance, with respect to a semiconductor substrate, a wafer substrate is immersed in a plating bath in accordance with the invention and serves as an electrode. A first metal layer (e.g. conductive layer) is deposited at a first reduction potential and a second metal layer (e.g. more resistive layer) is deposited at a second reduction potential, those first and second reduction potentials typically differing by at least about 0.2 V, then the metal of the first layer is again deposited at the first reduction potential and so on. A printed circuit board or lead frame substrate can be processed in similar fashion.

A solder resist also can be deposited on a printed circuit board substrate, or other substrate. Preferred solder compositions deposited by methods of the invention do not contain lead. Thus, for instance, in accordance with the invention, a mixture of tin and silver, tin and cobalt, tin and bismuth, tin and antimony, tin and zinc, tin and nickel and the like, may be deposited. More particularly, for a tin/silver layers, a layer of tin may be deposited at a first reduction potential, a layer of silver may be deposited at a second reduction potential, another layer of tin may be deposited at the first reduction potential and so on. Such solder resists may be coated onto copper circuit . traces on printed circuit boars.

All documents disclosed herein are incorporated herein by reference.

### Example 1

An electrolytic plating bath is provided that contains the following components admixed in water.

| Component | Concentration |
|---|---|
| CuSO₄ 5H₂O | 70 g/l |
| H₂SO₄ | 175 g/l |
| Cl | 50 ppm |
| Suppressor | 0.875 g/l |
| Brightener | 2.4 mg/l |
| Nickel Sulfamate | 1.5 Molar |

In the above composition the brightener is bis-sodium-sulfonopropyl-disulfide and the suppressor is a propylene glycol copolymer sold under the tradename L62D by BASF.

A semiconductor microchip wafer is plated using the above plating composition. The wafer was electrically attached to a cathode and the plating solution is pumped onto the surface of the wafer while rotating at upwards of 200 RPM. A first electrical current (mA/cm²) is applied suitably with DC wave form at 25° C. for 30 seconds or other defined period. A second electrical current distinct from the first current is then applied for 30 seconds or other defined period, and the first and second current cycles repeated multiple times.

The foregoing description of the invention is merely illustrative thereof, and it is understood that variations and modifications can be effected without departing from the spirit or scope of the invention as set forth in the following claims.

What is claimed is:

1. A method for depositing multiple metal layers on a semiconductor substrate, comprising:
contacting a semiconductor substrate with an electrolytic plating composition, the plating composition comprising a copper metal source and a second metal source distinct from copper;
electrolytically depositing a first metal layer of copper on the semiconductor substrate at a first reduction potential;
electrolytically depositing a second metal layer on the semiconductor substrate at a second reduction potential distinct from the first reduction potential.

2. The method of claim 1 wherein the first metal layer is a substantially homogenous copper metal layer.

3. The method of claim 1 wherein the second metal layer is a copper alloy.

4. The method of claim 1 wherein the second metal layer comprises one or more of zinc, tantalum, beryllium, magnesium, nickel, titanium, tin, palladium, silver, and cadmium.

5. The method of claim 1 wherein the second metal layer is a copper alloy that comprises one or more of zinc, tantalum, beryllium, magnesium, nickel, titanium, tin, palladium, silver, and cadmium.

6. The method of claim 1 wherein the first and second reduction potentials differ by at least about 0.2 V.

7. The method of claim 1 wherein a plurality of first metal layer are deposited with a plurality of alternating second metal layers.

8. The method of claim 1 wherein the first metal layer is effectively conductive and the second metal layer is substantially less conductive than the first layer.

9. The method of claim 1 wherein the first metal layer functions as an electrical circuit, and the second metal layer functions as an insulator layer.

10. The method of claim 1 wherein the substrate is a lead of a semiconductor device, or an interconnect of a semiconductor device.

11. A method for depositing multiple metal layers on a printed circuit board substrate having circuitry thereon, comprising:
contacting a printed circuit board substrate with an electrolytic plating composition, the plating composition comprising a copper metal source and a second metal source distinct from copper;
electrolytically depositing a first metal layer of copper on the printed circuit board substrate at a first reduction potential;
electrolytically depositing a second metal layer on the printed circuit board substrate at a second reduction potential distinct from the first reduction potential.

12. The method of claim 11 wherein the first metal layer is a substantially homogenous copper metal layer.

13. The method of claim 11 wherein the second metal layer is a copper alloy.

14. The method of claim 11 wherein the second metal layer comprises one or more of zinc, tantalum, beryllium, magnesium, nickel, titanium, tin, palladium, silver, and cadmium.

15. The method of claim 11 wherein the second metal layer is a copper alloy that comprises one or more of zinc, tantalum, beryllium, magnesium, nickel, titanium, tin, palladium, silver, and cadmium.

16. The method of claim 11 wherein the first and second reduction potentials differ by at least about 0.2 V.

17. The method of claim 11 wherein a plurality of first metal layer are deposited with a plurality of alternating second metal layers.

18. The method of claim 11 wherein the first metal layer is effectively conductive and the second metal layer is substantially less conductive than the first layer.

19. The method of claim 11 wherein the first metal layer functions as an electrical circuit, and the second metal layer functions as an insulator layer.

20. The method of claim 11 wherein a solder material is deposited on the substrate.

21. A method for depositing multiple metal layers on an electronic device substrate, comprising:
contacting the electronic device substrate with an electrolytic plating composition, the plating composition comprising a first metal source and a second metal source distinct from the first metal;
electrolytically depositing a layer of the first metal layer on the substrate at a first reduction potential;
electrolytically depositing a second metal layer on the substrate at a second reduction potential distinct from the first reduction potential.

22. The method of claim 21 wherein the substrate is a semiconductor substrate.

23. The method of claim 21 wherein the substrate is a semiconductor package substrate.

24. The method of claim 21 wherein the substrate is a multi-chip module, chip capicator, chip resistor, lead frame, or an opto-electronic device.

25. The method of claim 21 wherein the first metal layer is a substantially homogenous tin metal layer.

26. The method of claim 21 wherein the second metal layer is a tin alloy.

27. The method of claim 21 wherein the second metal layer comprises one or more of zinc, nickel, silver, antimony, bismuth, indium, cobalt, and copper.

28. The method of claim 21 wherein the first and second reduction potentials differ by at least about 0.2 V.

29. The method of claim 21 wherein a plurality of first metal layer are deposited with a plurality of alternating second metal layers.

30. The method of any one of claims 21 through 30 wherein the first metal layer is effectively conductive and the second metal layer is substantially less conductive than the first layer.

31. The method of claim 21 wherein the first and second metal layers are deposited from a single plating bath.
